(19) United States
(12) Patent Application Publication
(10) Pub. No.: US 2024/0130201 A1
(43) Pub. Date: Apr. 18, 2024

(54) DISPLAY APPARATUS AND METHOD OF MANUFACTURING THE SAME

(71) Applicant: Samsung Display Co., Ltd., Yongin-si (KR)

(72) Inventor: Euikang Heo, Yongin-si (KR)

(21) Appl. No.: 18/487,843

(22) Filed: Oct. 16, 2023

(30) Foreign Application Priority Data
Oct. 17, 2022 (KR) 10-2022-0133614

(51) Int. Cl. H10K 59/80; H10K 71/60

(52) U.S. Cl. CPC H10K 59/874; H10K 71/60

(57) ABSTRACT

A method of manufacturing a display apparatus is provided, the method including cleaning a surface of a substrate with an etchant containing fluorine (F) or a chemical solution of hydrofluoric acid (HF), and forming a bottom metal layer on the surface of the substrate, the bottom metal layer including a first layer and a second layer on the first layer, wherein a surface roughness of the substrate after cleaning is greater than a surface roughness of the substrate before cleaning.

### CROSS-REFERENCE TO RELATED APPLICATION

This application claims priority to and the benefit of Korean Patent Application No. 10-2022-0133614, filed on Oct. 17, 2022, in the Korean Intellectual Property Office, the entire disclosure of which is hereby incorporated by reference.

### BACKGROUND

### 1. Field

One or more embodiments relate to a display apparatus and a method of manufacturing a display apparatus.

### 2. Description of the Related Art

A display apparatus visually displays data. A display apparatus is utilized as a display unit for miniaturized products such as mobile phones, and is utilized as a display unit for large-scale products such as televisions.

Recently, the usage of display apparatuses has diversified. In addition, as display apparatuses have become thinner and lighter, their range of use has gradually extended.

As a display apparatus is variously utilized, there may be one or more suitable methods of designing the shape of a display apparatus, and also, functions that may be combined or associated with a display apparatus have increased.

### SUMMARY

Aspects of one or more embodiments of the present disclosure are directed towards a display apparatus in which copper (Cu) hillock is prevented or reduced from occurring even when a buffer layer is deposited on a bottom metal layer including Cu under a high temperature condition (e.g., about 370° or more), and a method of manufacturing the display apparatus. However, such a technical problem is an example, and the present disclosure is not limited thereto.

Additional aspects will be set forth in part in the description which follows and, in part, will be apparent from the description, or may be learned by practice of the presented embodiments of the disclosure.

According to one or more embodiments of the present disclosure, a method of manufacturing a display apparatus includes cleaning a surface of a substrate with an etchant containing fluorine (F) or a chemical solution of hydrofluoric acid (HF), and forming a bottom metal layer on the surface of the substrate, the bottom metal layer including a first layer and a second layer on the first layer, wherein a surface roughness of the substrate after cleaning is greater than a surface roughness of the substrate before cleaning.

In one or more embodiments, the first layer may include a first material, and the second layer may include a second material that is different from the first material.

In one or more embodiments, the first material may include titanium (Ti), and the second material may include copper (Cu).

In one or more embodiments, the method may further include, after the forming of the bottom metal layer, forming a buffer layer on the bottom metal layer.

In one or more embodiments, the buffer layer may include a first buffer layer and a second buffer layer that are sequentially stacked.

In one or more embodiments, the first buffer layer and the second buffer layer may include different materials.

In one or more embodiments, the first buffer layer may include silicon nitride (SiNₓ) and the second buffer layer may include silicon oxide (SiOₓ).

In one or more embodiments, in an X-ray diffraction spectrum of the first layer by an X-ray diffraction analysis, a peak on a (002) plane may be greater than a peak on a (103) plane.

In one or more embodiments, in an X-ray diffraction spectrum of the second layer by an X-ray diffraction analysis, a peak on a (111) plane may be greater than a peak on a (220) plane.

In one or more embodiments, in an X-ray diffraction spectrum of the second layer by an X-ray diffraction analysis, a ratio (P1/P2) of a (200) plane peak (P1) to a (111) plane peak (P2) may be 0.3 or more.

In one or more embodiments, the method may further include, after the forming of the buffer layer, forming a semiconductor layer on the buffer layer, and forming a gate electrode on the semiconductor layer.

According to one or more embodiments of the present disclosure, a display apparatus includes a substrate, and a bottom metal layer disposed on the substrate and including a first layer and a second layer on the first layer, wherein, in an X-ray diffraction spectrum of the second layer by an X-ray diffraction analysis, a (111) plane peak is greater than a (220) plane peak.

In one or more embodiments, the first layer may include a first material, and the second layer may include a second material that is different from the first material.

In one or more embodiments, the first material may include titanium (Ti), and the second material may include copper (Cu).

In one or more embodiments, the display apparatus may further include a buffer layer disposed on the bottom metal layer.

In one or more embodiments, the buffer layer may include a first buffer layer and a second buffer layer that are sequentially stacked.

In one or more embodiments, the first buffer layer and the second buffer layer may include different materials.

In one or more embodiments, the first buffer layer may include silicon nitride (SiNₓ) and the second buffer layer may include silicon oxide (SiOₓ).

In one or more embodiments, in an X-ray diffraction spectrum of the first layer by an X-ray diffraction analysis, a peak on a (002) plane may be greater than a peak on a (103) plane.

In one or more embodiments, in an X-ray diffraction spectrum of the second layer by an X-ray diffraction analysis, a ratio (P1/P2) of a (200) plane peak (P1) to a (111) plane peak (P2) may be 0.3 or more.

These and/or other aspects will become apparent and more readily appreciated from the following description of the embodiments, the accompanying drawings, and the claims.

### BRIEF DESCRIPTION OF THE DRAWINGS

The above and other aspects, features, and/or principles of certain embodiments of the disclosure will be more apparent from the following description taken in conjunction with the accompanying drawings, in which:

FIG. 1 is a schematic plan view of a display apparatus according to one or more embodiments of the present disclosure;

FIG. 2 is a schematic cross-sectional view of a display apparatus according to one or more embodiments of the present disclosure;

FIGS. 3-5 are schematic cross-sectional views showing a method of manufacturing a display apparatus, according to one or more embodiments of the present disclosure;

FIGS. 6A and 6B are views showing surface states of Sample #1 and Sample #5, respectively;

FIG. 7 is a graph showing X-ray diffraction characteristics of Sample #2 and Sample #6; and

FIGS. 8 and 9 are graphs showing X-ray diffraction characteristics of Sample #3 and Sample #7, respectively.

### DETAILED DESCRIPTION

The present disclosure may be modified in many alternate forms, and thus specific embodiments will be illustrated in the drawings and described in more detail. It should be understood, however, that they are not intended to limit the present disclosure to the particular forms disclosed, but rather, are intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, duplicative descriptions thereof may not be provided.

As used herein, the term “and/or” includes any and all combinations of one or more of the associated listed items. Expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

As the present disclosure allows for one or more suitable changes and numerous embodiments, certain embodiments will be illustrated in the drawings and described in the written description. Effects and features of the disclosure, and methods for achieving them will be clarified with reference to embodiments described below in more detail with reference to the drawings. However, the present disclosure is not limited to the following embodiments and may be embodied in one or more suitable forms.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an,” and “the” are intended to include the plural forms as well, unless the context clearly indicates otherwise.

It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

It will be further understood that, when a layer, region, or component is referred to as being “on” another layer, region, or component, it can be directly or indirectly on the other layer, region, or component. For example, intervening layers, regions, or components may be present. In addition, it will also be understood that when an element or layer is referred to as being “between” two elements or layers, it can be the only element or layer between the two elements or layers, or one or more intervening elements or layers may also be present.

Sizes of elements in the drawings may be exaggerated or reduced for convenience of explanation. As an example, the size and thickness of each element shown in the drawings may be arbitrarily represented for convenience of description, and thus, the present disclosure is not necessarily limited thereto.

In the present specification, “A and/or B” means A or B, or A and B. In the present specification, “at least one of A and B” means A or B, or A and B.

As used herein, when a wiring is referred to as “extending in a first direction or a second direction,” it means that the wiring not only extends in a straight line shape but also extends in a zigzag or in a curve in the first direction or the second direction.

As used herein, “in a plan view” means that an object is viewed from above, and “in a cross-sectional view” means that a vertical cross-section of the object is viewed from a lateral side. As used herein, “overlapping” includes overlapping “in a plan view” and “in a cross-sectional view.”

Hereinafter, embodiments of the present disclosure are described in more detail with reference to the accompanying drawings. When description is made with reference to the drawings, like reference numerals are used for like or corresponding elements.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

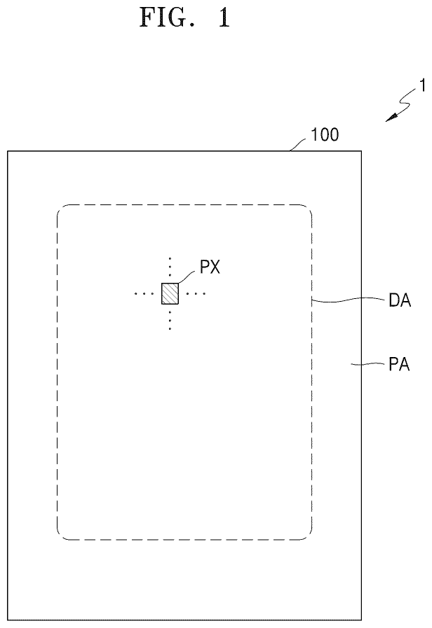

FIG. 1 is a schematic plan view of a display apparatus 1 according to one or more embodiments of the present disclosure.

Referring to FIG. 1, the display apparatus 1 includes a display area DA configured to display images and a peripheral area PA arranged around the display area DA. The display apparatus 1 may display images to the outside by utilizing light emitted from the display area DA.

A substrate 100 may include glass or a polymer resin. In one or more embodiments, the substrate 100 may include a flexible material. Here, the flexible material may be a material that is easily warped, bendable, foldable, or rollable. As an example, the flexible material may include ultra-thin glass, metal, or plastic.

Pixels PX including one or more suitable display elements such as an organic light-emitting diode OLED (also referred to as an organic light-emitting element) may be arranged in the display area DA of the substrate 100. The pixel PX may be provided in plurality. The plurality of pixels PX may be arranged in one or more suitable configurations such as a stripe configuration, a pentile configuration, a mosaic configuration, and/or the like to display images.

In one or more embodiments, in a plan view, the display area DA may be provided in a rectangular shape as shown in FIG. 1. In one or more embodiments, the display area DA may be provided in a polygonal shape such as a triangle, a pentagon, a hexagon, and/or the like, a circular shape, an elliptical shape, an irregular shape, and/or the like.

The peripheral area PA of the substrate 100 is a region around the display area DA and where images are not displayed. Pads may be arranged in the peripheral area PA, wherein one or more suitable wirings, a printed circuit board or a driver integrated circuit (IC) chip configured to transfer electric signals to the display area DA are attached to the pads.

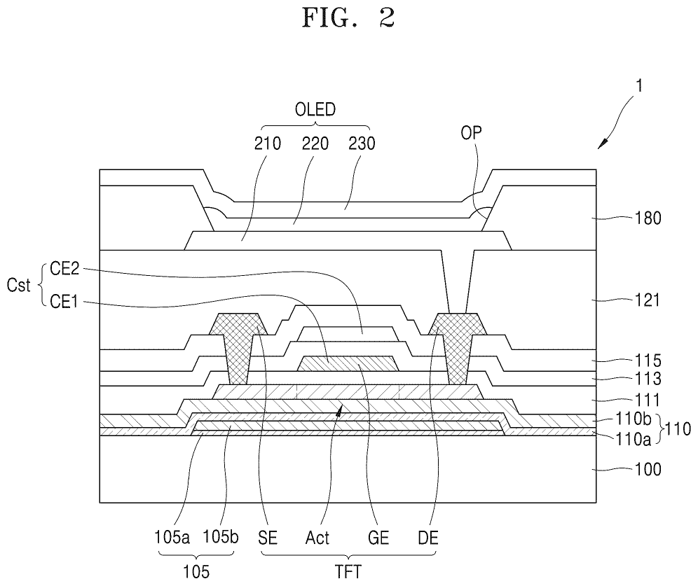

FIG. 2 is a schematic cross-sectional view of the display apparatus 1 according to one or more embodiments of the present disclosure.

Referring to FIG. 2, the display apparatus 1 may include the substrate 100, a thin-film transistor TFT, and a light-emitting element OLED.

The substrate 100 may include glass or a polymer resin. In this case, the polymer resin may include at least one of polyethersulfone, polyarylate, polyetherimide, polyethylene naphthalate, polyethylene terephthalate, polyphenylene sulfide, polyimide, polycarbonate, cellulose triacetate, cellulose acetate propionate, and/or the like. The substrate 100 may have a structure in which a layer including an organic material and a layer including an inorganic material are alternately stacked. As an example, the substrate 100 may include a first base layer, a first barrier layer, a second base layer, and a second barrier layer that are sequentially stacked.

A bottom metal layer 105 may be disposed on the substrate 100. The bottom metal layer 105 may be directly disposed on the substrate 100. The bottom metal layer 105 may include a first layer 105a and a second layer 105b. The first layer 105a of the bottom metal layer 105 may be disposed on the substrate 100, and the second layer 105b of the bottom metal layer 105 may be disposed on the first layer 105a.

The bottom metal layer 105 may include at least one of aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The bottom metal layer 105 may include a single layer or a multi-layer. In one or more embodiments, the first layer 105a of the bottom metal layer 105 may include a first material, and the second layer 105b of the bottom metal layer 105 may include a second material. The first material and the second material may each include one of aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The first material may be different from the second material. As an example, the first material may be titanium (Ti), and the second material may be copper (Cu). For example, the first layer 105a of the bottom metal layer 105 may include titanium (Ti), and the second layer 105b of the bottom metal layer 105 may include copper (Cu).

As described above, the substrate 100 may include glass, the first layer 105a of the bottom metal layer 105 may include titanium (Ti), and the second layer 105b of the bottom metal layer 105 may include copper (Cu). In this case, the first layer 105a including titanium (Ti) may be directly disposed on the substrate 100 including glass, and the second layer 105b including copper (Cu) may be directly disposed on the first layer 105a including titanium (Ti).

In one or more embodiments, in an X-ray diffraction spectrum of the first layer 105a by an X-ray diffraction analysis, a peak on a (002) plane may be greater than a peak on a (103) plane. This is described below in more detail.

In one or more embodiments, in an X-ray diffraction spectrum of the second layer 105b by an X-ray diffraction analysis, a ratio (P1/P2) of a peak P1 on a (200) plane to a peak P2 on a (111) plane may be 0.3 or more. The peak on the (111) plane may be greater than a peak on the (220) plane. This is described below in more detail.

In one or more embodiments, a buffer layer 110 may be disposed on the bottom metal layer 105. The buffer layer 110 may be directly disposed on the bottom metal layer 105 or the substrate 100. As an example, the buffer layer 110 may be disposed on the bottom metal layer 105 or directly disposed on the substrate 100 on which the bottom metal layer 105 is not disposed. The buffer layer 110 may reduce or block penetration of foreign materials, moisture, or external air from below the substrate 100.

The buffer layer 110 may include a first buffer layer 110a and a second buffer layer 110b. The first buffer layer 110a may be disposed on the bottom metal layer 105, and the second buffer layer 110b may be disposed on the first buffer layer 110a.

The buffer layer 110 may include an inorganic material such as silicon nitride (SiNₓ), silicon oxide (SiOₓ), and/or silicon oxynitride (SiON). In one or more embodiments, the first buffer layer 110a and the second buffer layer 110b may include different materials. As an example, the first buffer layer 110a may include silicon nitride (SiNₓ), and the second buffer layer 110b may include silicon oxide (SiOₓ). However, the present disclosure is not limited thereto. The first buffer layer 110a may include the same material as a material of the second buffer layer 110b.

The thin-film transistor TFT may be disposed on the buffer layer 110. The thin-film transistor TFT may include a semiconductor layer Act, a gate electrode GE, a source electrode SE, and a drain electrode DE.

First, the semiconductor layer Act may be disposed on the buffer layer 110. The semiconductor layer Act may include a channel region, a source region, and a drain region. The source region and the drain region may be respectively on two opposite sides of the channel region. The source region and the drain region may be doped with impurities. The impurities may include N-type or kind impurities or P-type or kind impurities.

In one or more embodiments, the semiconductor layer Act may include at least one of an oxide semiconductor material and/or a silicon semiconductor material. In the case where the semiconductor layer Act includes an oxide semiconductor material, the semiconductor layer Act may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), aluminum (AI), cesium (Cs), cerium (Ce), and/or zinc (Zn). As an example, the semiconductor layer Act may include In-Ga—Zn-O (IGZO), In—Sn—Zn—O (ITZO), or In—Ga—Sn—Zn—O (IGTZO) containing metals such as indium (In), gallium (Ga), and stannum (Sn) (i.e., tin) in ZnO. In the case where the semiconductor layer Act includes a silicon semiconductor material, the semiconductor layer Act may include amorphous silicon or polycrystalline silicon.

In one or more embodiments, the gate electrode GE may be disposed over the semiconductor layer Act. The gate electrode GE may overlap the semiconductor layer Act with a first insulating layer 111 therebetween. For example, the semiconductor layer Act may be insulated from the gate electrode GE by the first insulating layer 111. The gate electrode GE may include at least one of aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The gate electrode GE may include a single layer or a multi-layer.

In one or more embodiments, the first insulating layer 111 may include at least one of silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). In this case, zinc oxide (ZnOₓ) may be zinc oxide (ZnO) and/or zinc peroxide (ZnO₂).

In one or more embodiments, a second insulating layer 113 may be disposed on the gate electrode GE. The second insulating layer 113 may include at least one of silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). In this case, zinc oxide (ZnOₓ) may be zinc oxide (ZnO) and/or zinc peroxide (ZnO₂).

In one or more embodiments, a capacitor Cst may be disposed on the buffer layer 110. The capacitor Cst may include a lower electrode CE1 and an upper electrode CE2. The lower electrode CE1 may overlap the upper electrode CE2 with the second insulating layer 113 therebetween. The gate electrode GE of the thin-film transistor TFT and the lower electrode CE1 of the capacitor Cst may be formed as one body. For example, the gate electrode GE of the thin-film transistor TFT may serve as the lower electrode CE1 of the capacitor Cst. As described above, the thin-film transistor TFT may overlap the capacitor Cst. However, the present disclosure is not limited thereto. As an example, the lower electrode CE1 of the capacitor Cst may be an element separated from the gate electrode GE of the thin-film transistor TFT and may be apart from the gate electrode GE of the thin-film transistor TFT.

The upper electrode CE2 may include aluminum (AI), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and may include a single layer or a multi-layer including the above materials.

In one or more embodiments, a third insulating layer 115 may be disposed on the upper electrode CE2. The third insulating layer 115 may include at least one of silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). In this case, zinc oxide (ZnOₓ) may be zinc oxide (ZnO) and/or zinc peroxide (ZnO₂).

In one or more embodiments, the source electrode SE and the drain electrode DE may be disposed on the third insulating layer 115. The source electrode SE and the drain electrode DE may each include a conductive material including molybdenum (Mo), aluminum (AI), copper (Cu), and/or titanium (Ti) and may include a single layer or a multi-layer including the above materials. As an example, the source electrode SE and the drain electrode DE may have a multi-layered structure of Ti/AI/Ti. The source electrode SE and the drain electrode DE may be respectively and electrically connected to the source region and the drain region of the semiconductor layer Act.

In one or more embodiments, an organic insulating layer 121 may be disposed on the source electrode SE and the drain electrode DE. The organic insulating layer 121 may include an organic insulating material including a general-purpose polymer such as polymethylmethacrylate (PMMA) or polystyrene (PS), polymer derivative(s) having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. Though it is shown in FIG. 2 that one organic insulating layer 121 is provided, the present disclosure is not limited thereto. The organic insulating layer 121 may be provided as a plurality of layers. As an example, the organic insulating layer 121 may include two layers, three layers, or four layers. In one or more embodiments, wirings and/or connection electrodes may be disposed between the plurality of organic insulating layers 121.

A light-emitting element may be disposed on the organic insulating layer 121. The light-emitting element may be the organic light-emitting element OLED. However, the present disclosure is not limited thereto. The light-emitting element may include an inorganic light-emitting element and a quantum-dot light-emitting element. Hereinafter, the case where the light-emitting element is an organic light-emitting element OLED is mainly described in more detail.

In one or more embodiments, the organic light-emitting element OLED may include a pixel electrode 210, an emission layer 220, and an opposite electrode 230. The pixel electrode 210 may be disposed on the organic insulating layer 121. The pixel electrode 210 may be electrically connected to the thin-film transistor TFT through a via hole defined in the organic insulating layer 121. The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In one or more embodiments, the pixel electrode 210 may include a reflective layer including silver (Ag), magnesium (Mg), aluminum (AI), platinum (Pt), palladium (Pd), gold (Au), nickel (Ni), neodymium (Nd), iridium (Ir), chrome (Cr), or a compound thereof. In one or more embodiments, the pixel electrode 210 may further include a layer on/under the reflective layer, the layer including ITO, IZO, ZnO, or In₂O₃.

A pixel-defining layer 180 may be disposed on the pixel electrode 210, the pixel-defining layer 180 including an opening OP exposing at least a portion of the pixel electrode 210. The opening OP defined in the pixel-defining layer 180 may expose at least a portion of the pixel-electrode 210. As an example, the opening OP defined in the pixel-defining layer 180 may expose a central portion of the pixel-electrode 210. An emission area of light emitted by the organic light-emitting element OLED may be defined by the opening OP.

The pixel-defining layer 180 may include an organic insulating material. In one or more embodiments, the pixel-defining layer 180 may include an inorganic insulating material, such as silicon oxide, silicon oxynitride, or silicon nitride. In one or more embodiments, the pixel-defining layer 180 may include an organic insulating material and an inorganic insulating material. In one or more embodiments, the pixel-defining layer 180 may include a light-blocking material and may be the color black (e.g., provided in black). The light-blocking material may include carbon black, carbon nanotubes, a resin or paste including black dye, metal particles, for example, nickel, aluminum, molybdenum, and/or an alloy thereof, metal oxide particles (e.g., chrome oxide) or metal nitride particles (e.g., chrome nitride). In the case where the pixel-defining layer 180 includes a light-blocking material, external light reflection by a metal structure arranged below the pixel-defining layer 180 may be reduced.

In one or more embodiments, a spacer may be disposed on the pixel-defining layer 180. The spacer may include an organic insulating material such as polyimide. In one or more embodiments, the spacer may include an inorganic insulating material such as silicon oxide, silicon nitride, and/or silicon oxynitride, or include an organic insulating material and an inorganic insulating material.

In one or more embodiments, the spacer may include the same material as that of the pixel-defining layer 180. In this case, the pixel-defining layer 180 and the spacer may be formed together during a mask process that uses a half-tone mask and/or the like. In one or more embodiments, the spacer may include a material that is different from a material of the pixel-defining layer 180.

The emission layer 220 may be disposed on the pixel electrode 210. The emission layer 220 may be disposed in the opening of the pixel-defining layer 180. The emission layer 220 may include a polymer organic material or a low-molecular weight organic material emitting light having a preset color.

A first functional layer may be disposed between the pixel electrode 210 and the emission layer 220, and a second functional layer may be disposed between the emission layer 220 and the opposite electrode 230. However, the present disclosure is not limited thereto. At least one of the first functional layer or the second functional layer may not be provided.

The first functional layer may include, for example, a hole transport layer (HTL), or include an HTL and a hole injection layer (HIL). The second functional layer may include an electron transport layer (ETL) and/or an electron injection layer (EIL). The first functional layer and/or the second functional layer may be common layers formed to cover the entirety of the substrate 100.

The opposite electrode 230 may include a conductive material having a low work function. As an example, the opposite electrode 230 may include a (semi) transparent layer (e.g., the opposite electrode may include a semi-transparent layer or a transparent layer) including silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), or an alloy thereof. In one or more embodiments, the opposite electrode 230 may further include a layer on the (semi) transparent layer, the layer including ITO, IZO, ZnO, or In₂O₃.

In one or more embodiments, a capping layer may be further disposed on the opposite electrode 230. The capping layer may include lithium fluoride (LiF), an inorganic material, and/or an organic material.

In one or more embodiments, an encapsulation member may be disposed on the organic light-emitting diode OLED. The encapsulation member may be a thin-film encapsulation layer including at least one inorganic layer and/or at least one organic layer. In one or more embodiments, the encapsulation layer may be an encapsulation substrate.

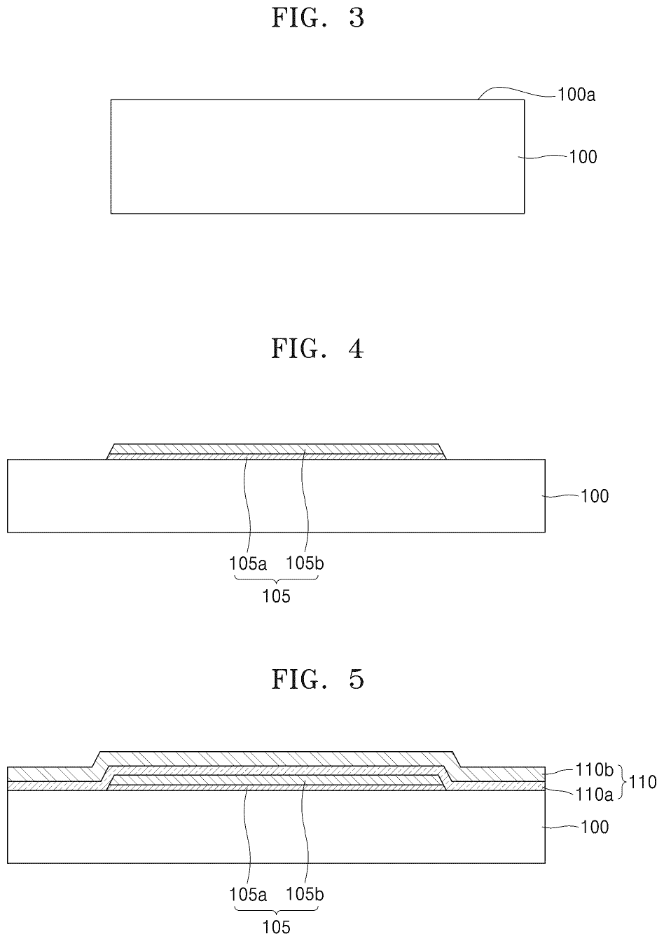

FIGS. 3 to 5 are schematic cross-sectional views showing a method of manufacturing a display apparatus, according to one or more embodiments of the present disclosure.

Hereinafter, the method of manufacturing a display apparatus is sequentially described with reference to FIGS. 3 to 5.

Referring to FIGS. 3 to 5, the method of manufacturing the display apparatus may include cleaning a surface 100a of the substrate 100 with an etchant containing fluorine (F) or a chemical solution of hydrofluoric acid (HF), forming a bottom metal layer 105 on the surface 100a of the substrate 100, the bottom metal layer 105 including a first layer 105a and a second layer 105b on the first layer 105a, and forming the buffer layer 110 on the bottom metal layer 105.

First, referring to FIG. 3, the surface 100a of the substrate 100 may be cleaned with the etchant containing fluorine (F) or the chemical solution of hydrofluoric acid (HF). In one or more embodiments, the substrate 100 may include glass. However, the present disclosure is not limited thereto. As an example, the substrate 100 may include polymer resin. In one or more embodiments, before the surface 100a of the substrate 100 is cleaned with the etchant containing fluorine (F) or the chemical solution of hydrofluoric acid (HF), the surface 100a of the substrate 100 may be cleaned by utilizing a cleaning solution including tetramethylammonium hydroxide (TMAH).

In one or more embodiments, in the case where the surface 100a of the substrate 100 is cleaned with the etchant containing fluorine (F) or the chemical solution of hydrofluoric acid (HF), the surface roughness of the substrate 100 after the cleaning may be greater than the surface roughness of the substrate 100 before the cleaning. For example, in the case where the surface 100a of the substrate 100 is cleaned with the etchant containing fluorine (F) or the chemical solution of hydrofluoric acid (HF), the surface 100a of the substrate 100 may be etched, and accordingly, the surface roughness of the substrate 100 after the cleaning may increase compared to the surface roughness of the substrate 100 before the cleaning. As an example, the surface roughness of the substrate 100 before cleaning is about 0.22 nm, but the surface of the substrate 100 after cleaning the surface 100a of the substrate 100 with an etchant containing fluorine (F) or a chemical solution of hydrofluoric acid (HF) is about 0.31 nm, which shows that the surface roughness of the substrate 100 may increase. This is described in more detail below.

Referring to FIG. 4, the bottom metal layer 105 may be formed on the substrate 100. For example, after the surface 100a of the substrate 100 is cleaned with an etchant containing fluorine (F) or a chemical solution of hydrofluoric acid (HF), the bottom metal layer 105 including the first layer 105a and the second layer 105b may be formed on the substrate 100. The first layer 105a of the bottom metal layer 105 may be formed on the substrate 100, and the second layer 105b of the bottom metal layer 105 may be formed on the first layer 105a.

The bottom metal layer 105 may include at least one of aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The bottom metal layer 105 may include a single layer or a multi-layer. In one or more embodiments, the first layer 105a of the bottom metal layer 105 may include a first material, and the second layer 105b of the bottom metal layer 105 may include a second material. The first material and the second material may each include one of aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The first material may be different from the second material. As an example, the first material may be titanium (Ti), and the second material may be copper (Cu). For example, the first layer 105a of the bottom metal layer 105 may include titanium (Ti), and the second layer 105b of the bottom metal layer 105 may include copper (Cu).

In the case where the surface 100a of the substrate 100 is cleaned with an etchant containing fluorine (F) or a chemical solution of hydrofluoric acid (HF), the surface roughness of the substrate 100 may increase compared to the case where the surface 100a of the substrate 100 is not cleaned with an etchant containing fluorine (F) or a chemical solution of hydrofluoric acid (HF). In one or more embodiments, in the case where the surface roughness of the substrate 100 increases, the surface roughness of the first layer 105a formed on the substrate 100 may increase. For example, in the structure in which the first layer 105a is formed on the substrate 100, the surface roughness of the first surface 105a in the case where the surface 100a of the substrate 100 is cleaned with an etchant containing fluorine (F) or a chemical solution of hydrofluoric acid (HF) may be greater than the surface roughness of the first layer 105a in the case where the surface 100a of the substrate 100 is not cleaned with an etchant containing fluorine (F) or a chemical solution of hydrofluoric acid (HF). For example, in the case where the surface 100a of the substrate 100 is cleaned with an etchant containing fluorine (F) or a chemical solution of hydrofluoric acid (HF), the surface roughness of the substrate 100 may increase, and also, the surface roughness of the first layer 105a may increase. This is described below in more detail.

In the case where the surface roughness of the substrate 100 increases, the surface roughness of the first layer 105a formed on the substrate 100 may increase. However, even in the case where the surface roughness of the substrate 100 and the surface roughness of the first layer 105a increase, the surface roughness of the second layer 105b formed on the first layer 105a may reduce. For example, in the structure in which the first layer 105a and the second layer 105b are sequentially formed on the substrate 100, the surface roughness of the second layer 105b in the case where the surface 100a of the substrate 100 is cleaned with an etchant containing fluorine (F) or a chemical solution of hydrofluoric acid (HF) may be less than the surface roughness of the second layer 105b in the case where the surface 100a of the substrate 100 is not cleaned with an etchant containing fluorine (F) or a chemical solution of hydrofluoric acid (HF). For example, in the case where the surface 100a of the substrate 100 is cleaned with an etchant containing fluorine (F) or a chemical solution of hydrofluoric acid (HF), the surface roughness of the first layer 105a may increase but the surface roughness of the second layer 105b may reduce. This is described in more detail below.

In one or more embodiments, in an X-ray diffraction spectrum of the first layer 105a by an X-ray diffraction analysis, a peak on a (002) plane may be greater than a peak on a (103) plane. This is described in more detail below.

In one or more embodiments, in an X-ray diffraction spectrum of the second layer 105b by an X-ray diffraction analysis, a ratio (P1/P2) of a peak P1 on a (200) plane to a peak P2 on a (111) plane may be 0.3 or more. The peak on the (111) plane may be greater than a peak on the (220) plane. This is described in more detail below.

Referring to FIG. 5, after the bottom metal layer 105 is formed on the substrate 100, the buffer layer 110 may be formed on the bottom metal layer 105. The buffer layer 110 may include the first buffer layer 110a and the second buffer layer 110b. The first buffer layer 110a may be formed on the bottom metal layer 105, and the second buffer layer 110b may be formed on the first buffer layer 110a.

The buffer layer 110 may include an inorganic material such as silicon nitride (SiNₓ), silicon oxide (SiOₓ), and/or silicon oxynitride (SiON). In one or more embodiments, the first buffer layer 110a and the second buffer layer 110b may include different materials. As an example, the first buffer layer 110a may include silicon nitride (SiNₓ), and the second buffer layer 110b may include silicon oxide (SiOₓ). However, the present disclosure is not limited thereto. The first buffer layer 110a may include the same material as a material of the second buffer layer 110b.

As shown in FIG. 2, the thin-film transistor TFT (see, e.g., FIG. 2) and the organic light-emitting element OLED may be formed on the buffer layer 110, wherein the thin-film transistor TFT includes the semiconductor layer Act (see, e.g., FIG. 2), the gate electrode GE (see, e.g., FIG. 2), the source electrode SE (see, e.g., FIG. 2), and the drain electrode DE (see, e.g., FIG. 2), and the organic light-emitting element OLED includes the pixel electrode 210 (see, e.g., FIG. 2), the emission layer 220 (see, e.g., FIG. 2), and the opposite electrode 230 (see, e.g., FIG. 2).

For example, the semiconductor layer Act may be formed on the buffer layer 110, and the first insulating layer 111 (see, e.g., FIG. 2) may be formed on the semiconductor layer Act. The gate electrode GE may be formed on the first insulating layer 111, and the second insulating layer 113 (see, e.g., FIG. 2) may be formed on the gate electrode GE. The upper electrode CE2 (see, e.g., FIG. 2) may be formed on the second insulating layer 113, the third insulating layer 115 (see, e.g., FIG. 2) may be formed on the upper electrode CE2, and the source electrode SE and the drain electrode DE may be formed on the third insulating layer 115.

In one or more embodiments, the organic insulating layer 121 (see, e.g., FIG. 2) may be formed on the source electrode SE and the drain electrode DE, the pixel electrode 210 and the pixel-defining layer 180 (see, e.g., FIG. 2) may be formed on the organic insulating layer 121, and the emission layer 220 and the opposite electrode 230 may be formed on the pixel electrode 210.

When a deposition temperature of the buffer layer 110 is low, oxygen gas inside the buffer layer 110 may be discharged and the characteristics of an element formed on the buffer layer 110 may deteriorate. For example, when the buffer layer 110 is deposited at an excessively low temperature, oxygen gas inside the buffer layer 110 may be discharged and the characteristics of the thin-film transistor TFT formed on the buffer layer 110 may deteriorate. To prevent or reduce oxygen gas inside the buffer layer 110 from being discharged, the buffer layer 110 may be deposited at high temperatures.

Accordingly, the buffer layer 110 may be deposited at high temperatures (e.g., a temperature of 370° or more). However, when the buffer layer 110 is deposited at high temperatures (e.g., a temperature of 370° or more), copper nitride (CuNₓ) may be formed on a grain boundary of the second layer 105b of the bottom metal layer 105. In addition, copper atoms may move along the wall of copper nitride (CuNₓ) due to compressive stress caused by the deposition temperature (e.g., a temperature of 370° or more) of the buffer layer 110, and copper hillocks may occur on the surface of the second layer 105b of the bottom metal layer 105 due to stress caused by heat while the buffer layer 110 is deposited. In this case, due to copper hillocks formed on the surface of the second layer 105b of the bottom metal layer 105, the electrodes (e.g., the gate electrode GE, the upper electrode CE2, the source electrode SE, and the drain electrode DE) formed thereon may become curved, and defects may occur to the electrodes (e.g., the gate electrode GE, the upper electrode CE2, the source electrode SE, and the drain electrode DE).

Tables 1 and 2 show hillock occurrence levels and measurement results of a surface roughness in various samples. In Table 1, TMAH cleaning refers to cleaning the surface 100a of the substrate 100 utilizing a cleaning solution including TMAH, etchant cleaning refers to cleaning the surface 100a of the substrate 100 utilizing an etchant containing fluorine (F), and HF cleaning refers to cleaning the surface 100a of the substrate 100 utilizing a chemical solution of hydrofluoric acid (HF). For example, TMAH cleaning+etchant cleaning refers to cleaning the surface 100a of the substrate 100 utilizing a cleaning solution including TMAH and then cleaning the surface 100a of the substrate 100 utilizing an etchant containing fluorine (F). In addition, TMAH cleaning+HF cleaning refers to cleaning the surface 100a of the substrate 100 utilizing a cleaning solution including TMAH and then cleaning the surface 100a of the substrate 100 utilizing a chemical solution of hydrofluoric acid (HF).

In Table 1, Sample #2 and Sample #6 are cases where the first layer (Ti) is formed on the substrate (glass), Sample #3 and Sample #7 are cases where the first layer (Ti) and the second layer (Cu) are sequentially formed on the substrate (glass), and Sample #4, Sample #8, and Sample #9 are cases where the first layer (Ti), the second layer (Cu), and the buffer layer are formed on the substrate (glass). In this case, as described with reference to FIG. 2, the buffer layer includes the first buffer layer (SiNₓ) and the second buffer layer (SiOₓ).

In Table 2, a hillock occurrence level and an RMS roughness were measured utilizing an atomic force microscope (AFM).

TABLE 1
sample information

| | Process | |
|---|---|---|
| No. | condition | Stack structure |
| #1 | TMAH | Substrate (Glass) |
| #2 | cleaning | Substrate (Glass)/first layer (Ti) |
| #3 | | Substrate (Glass)/first layer (Ti)/ |
| | | second layer (Cu) |
| #4 | | Substrate (Glass)/first layer (Ti)/ |
| | | second layer (Cu)/Buffer |
| #5 | TMAH | Substrate (Glass) |
| #6 | cleaning + | Substrate (Glass)/first layer (Ti) |
| #7 | Etchant | Substrate (Glass)/first layer (Ti)/ |
| | cleaning | second layer (Cu) |
| #8 | (F included) | Substrate (Glass)/first layer (Ti)/ |
| | | second layer (Cu)/Buffer |
| #9 | TMAH | Substrate (Glass)/first layer (Ti)/ |
| | cleaning + | second layer (Cu)/Buffer |
| | HF cleaning | |

TABLE 2

| | | RMS Roughness | | | |
|---|---|---|---|---|---|
| | | (nm) | | Average | Standard |
| No. | Hillock level | 1 | 2 | value | deviation |
| #1 | — | 0.232 | 0.217 | 0.22 | 0.011 |
| #2 | | 0.277 | 0.265 | 0.27 | 0.008 |
| #3 | Strong | 3.634 | 3.616 | 3.63 | 0.013 |
| #4 | | 12.654 | 12.584 | 12.62 | 0.049 |
| #5 | — | 0.306 | 0.313 | 0.31 | 0.005 |
| #6 | | 0.504 | 0.504 | 0.50 | 0 |
| #7 | feeble/weak | 1.719 | 1.630 | 1.67 | 0.063 |
| #8 | | 3.363 | 3.872 | 3.62 | 0.360 |
| #9 | weak | 4.534 | 4.376 | 4.46 | 0.112 |

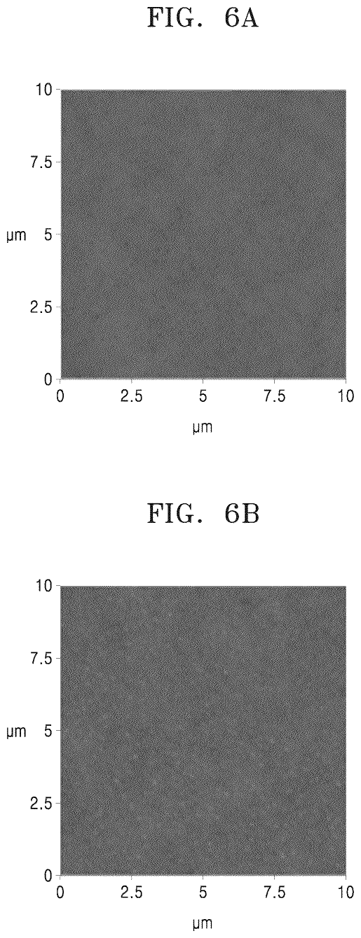

FIGS. 6A and 6B are views showing surface states of Sample #1 and Sample #5. For example, FIGS. 6A and 6B are views showing surface states of Sample #1 and Sample #5 measured utilizing an AFM.

Referring to Tables 1 and 2 and FIGS. 6A and 6B, it is determined that the surface roughness of the substrate 100 in the case where the surface 100a of the substrate 100 is cleaned utilizing an etchant containing fluorine (F) is greater than the surface roughness of the substrate 100 in the case where the surface 100a of the substrate 100 is not cleaned utilizing an etchant containing fluorine (F). For example, in the case where the surface 100a of the substrate 100 is cleaned utilizing an etchant containing fluorine (F), it may be determined that the surface roughness of the substrate 100 increases.

In addition, it may be determined that the surface roughness of the first layer (Ti) in the case where the surface 100a of the substrate 100 is cleaned utilizing an etchant containing fluorine (F) is greater than the surface roughness of the first layer (Ti) in the case where the surface 100a of the substrate 100 is not cleaned utilizing an etchant containing fluorine (F). However, it may be determined that the surface roughness of the second layer (Cu) in the case where the surface 100a of the substrate 100 is cleaned utilizing an etchant containing fluorine (F) is less than the surface roughness of the second layer (Cu) in the case where the surface 100a of the substrate 100 is not cleaned utilizing an etchant containing fluorine (F). For example, though the surface roughness of the first layer (Ti) in the case where the surface 100a of the substrate 100 is cleaned utilizing an etchant containing fluorine (F) may increase compared to the surface roughness of the first layer (Ti) in the case where the surface 100a of the substrate 100 is not cleaned utilizing an etchant containing fluorine (F), the surface roughness of the second layer (Cu) in the case where the surface 100a of the substrate 100 is cleaned utilizing an etchant containing fluorine (F) may be reduced compared to the surface roughness of the second layer (Cu) in the case where the surface 100a of the substrate 100 is not cleaned utilizing an etchant containing fluorine (F).

In the case where the surface 100a of the substrate 100 is cleaned utilizing an etchant containing fluorine (F), the surface roughness of the substrate 100 may increase and the surface roughness of the first layer (Ti) formed on the substrate 100 may increase. In the case where the surface roughness of the substrate 100 and the surface roughness of the first layer (Ti) increase, nucleation sites of copper (Cu) included in the second layer (Cu) may increase, and when nucleation sites of copper (Cu) increase, a grain size of copper (Cu) may be reduced. In addition, when the grain size of copper (Cu) is reduced, internal stress of the second layer (Cu) is reduced and the surface roughness of the second layer (Cu) may be reduced. For example, the surface roughness of the second layer (Cu) in the case where the surface 100a of the substrate 100 is cleaned utilizing an etchant containing fluorine (F) may be less than the surface roughness of the second layer (Cu) in the case where the surface 100a of the substrate 100 is not cleaned utilizing an etchant containing fluorine (F).

When the surface roughness of the second layer (Cu) is large, it may signify that a large amount of (or a large number of) copper hillocks are formed on the surface of the second layer (Cu), or that the size of the copper hillocks formed on the surface of the second layer (Cu) are large. In contrast, when the surface roughness of the second layer (Cu) is small, it may signify that a small amount of (or a small number of) copper hillocks are formed on the surface of the second layer (Cu), or that the size of the copper hillocks formed on the surface of the second layer (Cu) are small.

Accordingly, because the surface roughness of the second layer (Cu) in the case where the surface 100a of the substrate 100 is cleaned utilizing an etchant containing fluorine (F) is less than the surface roughness of the second layer (Cu) in the case where the surface 100a of the substrate 100 is not cleaned utilizing an etchant containing fluorine (F), in the case where the surface 100a of the substrate 100 is cleaned utilizing an etchant containing fluorine (F), the amount of (or the number of) copper hillocks (Cu hillocks) formed on the surface of the second layer (Cu) may be reduced, and the size of the Cu hillocks formed on the second layer (Cu) may be reduced compared to the case where the surface 100a of the substrate 100 is not cleaned utilizing an etchant containing fluorine (F).

In addition, it may be determined that the surface roughness of the buffer layer in the case where the surface 100a of the substrate 100 is cleaned utilizing an etchant containing fluorine (F) is less than the surface roughness of the buffer layer in the case where the surface 100a of the substrate 100 is not cleaned utilizing an etchant containing fluorine (F).

As described above, in the case where the second layer (Cu) has a large surface roughness, the surface roughness of the buffer layer formed on the second layer (Cu) may also have a large value. In contrast, in the case where the second layer (Cu) has a small surface roughness, the surface roughness of the buffer layer formed on the second layer (Cu) may also have a small value.

Accordingly, the surface roughness of the second layer (Cu) in the case where the surface 100a of the substrate 100 is cleaned utilizing an etchant containing fluorine (F) is reduced and the surface roughness of the buffer layer disposed on the second layer (Cu) may be reduced.

In addition, it may be determined that the surface roughness of the second layer (Cu) in the case where the surface 100a of the substrate 100 is cleaned utilizing a chemical solution of hydrofluoric acid (HF) is less than the surface roughness of the second layer (Cu) in the case where the surface 100a of the substrate 100 is not cleaned utilizing a chemical solution of hydrofluoric acid (HF). As an example, the surface roughness of the second layer (Cu) in the case where the surface 100a of the substrate 100 is cleaned utilizing a chemical solution of hydrofluoric acid (HF) is reduced and the surface roughness of the buffer layer disposed on the second layer (Cu) is reduced, as shown for example, in Sample #9.

In addition, it may be determined that, in the case where the surface 100a of the substrate 100 is cleaned with an etchant containing fluorine (F) or a chemical solution of hydrofluoric acid (HF), hillocks weakly occur on the surface of the second layer (Cu) compared to the case where the surface 100a of the substrate 100 is not cleaned with an etchant containing fluorine (F) or a chemical solution of hydrofluoric acid (HF).

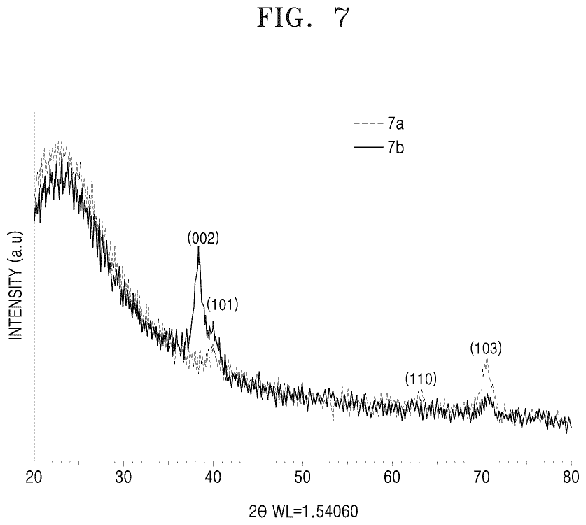

FIG. 7 is a view showing X-ray diffraction characteristics of Sample #2 and Sample #6. For example, in FIG. 7, line 7a shows X-ray diffraction characteristics of Sample #2, and line 7b shows X-ray diffraction characteristics of Sample #6. For example, line 7a corresponds to the case where the surface 100a of the substrate 100 is not cleaned with an etchant containing fluorine (F) or a chemical solution of hydrofluoric acid (HF), and line 7b corresponds to the case where the surface 100a of the substrate 100 is cleaned with an etchant containing fluorine (F).

Referring to Tables 1 and 2 and FIG. 7, it may be determined that, in the case where the surface 100a of the substrate 100 is cleaned with an etchant containing fluorine (F) or a chemical solution of hydrofluoric acid (HF), peaks on a (002) plane and a (101) plane increase and a peak on a (103) plane reduces in the X-ray diffraction spectrum of the first layer (Ti) compared to the case the surface 100a of the substrate 100 is not cleaned with an etchant containing fluorine (F) or a chemical solution of hydrofluoric acid (HF).

In one or more embodiments, in an X-ray diffraction spectrum of the first layer (Ti) by an X-ray diffraction analysis, a peak on a (002) plane may be greater than a peak on a (103) plane. For example, in the case where the surface 100a of the substrate 100 is cleaned with an etchant containing fluorine (F) or a chemical solution of hydrofluoric acid (HF), an orientation distribution in the film plane direction (002) of the first layer (Ti) may increase.

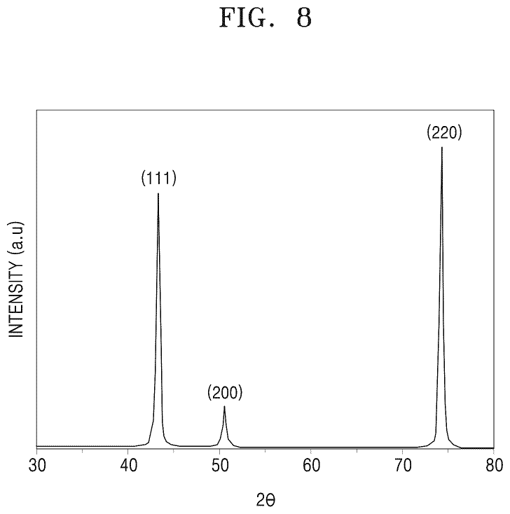

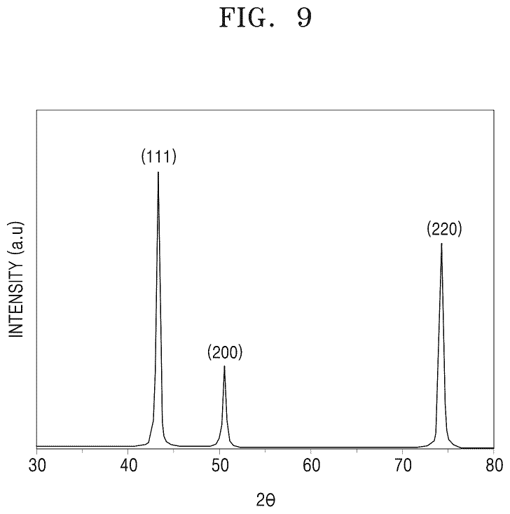

FIGS. 8 and 9 are graphs showing X-ray diffraction characteristics of Sample #3 and Sample #7, respectively. For example, FIG. 8 is a graph showing X-ray diffraction characteristics of Sample #3, and FIG. 9 is a graph showing X-ray diffraction characteristics of Sample #7. For example, FIG. 8 corresponds to the case where the surface 100a of the substrate 100 is not cleaned with an etchant containing fluorine (F) or a chemical solution of hydrofluoric acid (HF), and FIG. 9 corresponds to the case where the surface 100a of the substrate 100 is cleaned with an etchant containing fluorine (F).

Referring to Tables 1 and 2 and FIGS. 8 and 9, it may be determined that, in the case where the surface 100a of the substrate 100 is not cleaned with an etchant containing fluorine (F) or a chemical solution of hydrofluoric acid (HF), a peak on a (220) plane in the X-ray diffraction spectrum of the second layer (Cu) is greater than a peak on a (111) plane and also greater than a peak on a (200) plane. In addition, in the case where the surface 100a of the substrate 100 is not cleaned with an etchant containing fluorine (F) or a chemical solution of hydrofluoric acid (HF), a ratio (P4/P5) of a peak P4 on a (200) plane to a peak P5 on a (111) plane in the X-ray diffraction spectrum of the second layer (Cu) may be about 0.17, and a ratio (P6/P5) of a peak P6 on a (220) plane to a peak P5 on a (111) plane may be about 1.13.

In contrast, in the case where the surface 100a of the substrate 100 is cleaned with an etchant containing fluorine (F), it may be determined that a peak on a (111) plane is greater than a peak on a (200) plane and also greater than a peak on a (220) plane in the X-ray diffraction spectrum of the second layer (Cu). In addition, in the case where the surface 100a of the substrate 100 is cleaned with an etchant containing fluorine (F), a ratio (P1/P2) of a peak P1 on a (200) plane to a peak P2 on a (111) plane in the X-ray diffraction spectrum of the second layer (Cu) may be about 0.32, and a ratio (P3/P2) of a peak P3 on a (220) plane to a peak P2 on a (111) plane may be about 0.79.

In one or more embodiments, it may be determined that, in the case where the surface 100a of the substrate 100 is cleaned with an etchant containing fluorine (F) or a chemical solution of hydrofluoric acid (HF), a peak on a (220) plane may be reduced in the X-ray diffraction spectrum of the second layer (Cu) compared to the case where the surface 100a of the substrate 100 is not cleaned with an etchant containing fluorine (F) or a chemical solution of hydrofluoric acid (HF). In one or more embodiments, it may be determined that, in the case where the surface 100a of the substrate 100 is cleaned with an etchant containing fluorine (F) or a chemical solution of hydrofluoric acid (HF), a peak on a (200) plane and a peak on a (111) plane may increase in the X-ray diffraction spectrum of the second layer (Cu) compared to the case where the surface 100a of the substrate 100 is not cleaned with an etchant containing fluorine (F) or a chemical solution of hydrofluoric acid (HF). In this case, a peak on a (220) plane, a peak on a (200) plane, and a peak on a (111) plane may be relative to one another.

In one or more embodiments, in the case where the surface 100a of the substrate 100 is cleaned with an etchant containing fluorine (F) or a chemical solution of hydrofluoric acid (HF), a ratio (P1/P2) of a peak P1 on a (200) plane to a peak P2 on a (111) plane may be 0.3 or more in the X-ray diffraction spectrum of the second layer (Cu). For example, in the case where the surface 100a of the substrate 100 is cleaned with an etchant containing fluorine (F) or a chemical solution of hydrofluoric acid (HF), a peak P1 on a (200) plane may increase in the X-ray diffraction spectrum of the second layer (Cu), and thus, a ratio (P1/P2) of a peak P1 on a (200) plane to a peak P2 on a (111) plane may be 0.3 or more compared to the case where the surface 100a of the substrate 100 is not cleaned with an etchant containing fluorine (F) or a chemical solution of hydrofluoric acid (HF).

In one or more embodiments, in the case where the surface 100a of the substrate 100 is cleaned with an etchant containing fluorine (F) or a chemical solution of hydrofluoric acid (HF), a ratio (P3/P2) of a peak P3 on a (220) plane to a peak P2 on a (111) plane may be 0.3 or more in the X-ray diffraction spectrum of the second layer (Cu). For example, in the case where the surface 100a of the substrate 100 is cleaned with an etchant containing fluorine (F) or a chemical solution of hydrofluoric acid (HF), a peak P3 on a (220) plane may reduce and a peak P2 on a (111) plane may increase in the X-ray diffraction spectrum of the second layer (Cu), and thus, a ratio (P3/P2) of the peak P3 on the (220) plane to the peak P2 on the (111) plane may be 1 or less compared to the case where the surface 100a of the substrate 100 is not cleaned with an etchant containing fluorine (F) or a chemical solution of hydrofluoric acid (HF).

In one or more embodiments, in the case where the surface 100a of the substrate 100 is cleaned with an etchant containing fluorine (F) or a chemical solution of hydrofluoric acid (HF), a (220) orientation distribution of the second layer (Cu) may be reduced compared to the case where the surface 100a of the substrate 100 is not cleaned with an etchant containing fluorine (F) or a chemical solution of hydrofluoric acid (HF). For example, in the case where the surface 100a of the substrate 100 is cleaned with an etchant containing fluorine (F) or a chemical solution of hydrofluoric acid (HF), an orientation distribution in the film plane direction (002) of the first layer (Ti) may increase, and thus, a (220) orientation distribution of the second layer (Cu) on the first layer (Ti) may be reduced compared to the case where the surface 100a of the substrate 100 is not cleaned with an etchant containing fluorine (F) or a chemical solution of hydrofluoric acid (HF).

Generally, as a (220) orientation distribution inside the copper (Cu) thin film increases, compressive stress inside the copper (Cu) thin film increases. In one or more embodiments, in the case where the surface 100a of the substrate 100 is cleaned with an etchant containing fluorine (F) or a chemical solution of hydrofluoric acid (HF), a (220) orientation distribution of the second layer (Cu) may be reduced, and thus, compressive stress inside the second layer (Cu) may be reduced compared to the case where the surface 100a of the substrate 100 is not cleaned with an etchant containing fluorine (F) or a chemical solution of hydrofluoric acid (HF). Accordingly, because compressive stress inside the second layer (Cu) is reduced, the occurrence of hillocks on the surface of the second layer (Cu) may be reduced even when the buffer layer is deposited under high temperatures (e.g., a temperature of 370° C. or higher).

In one or more embodiments, the bottom metal layer 105 may be formed on the substrate 100 and the buffer layer 110 may be formed on the bottom metal layer 105. The bottom metal layer 105 may include the first layer 105a and the second layer 105b. The first layer 105a may be formed on the bottom metal layer 105, and the second layer 105b may be formed on the first layer 105a. In this case, the substrate 100 may include glass, the first layer 105a may include titanium (Ti), and the second layer 105b may include copper (Cu).

In the case where the surface 100a of the substrate 100 is cleaned with an etchant containing fluorine (F) or a chemical solution of hydrofluoric acid (HF), at least a portion of the surface 100a of the substrate 100 may be etched and the surface roughness of the substrate 100 may increase. In one or more embodiments, because the surface roughness of the substrate 100 increases, the surface roughness of the first layer 105a formed on the substrate 100 may also increase compared to the case where the surface 100a is not cleaned. However, in the case where the surface roughness of the first layer 105a is increased, deposition stress of the second layer 105b is reduced and the surface roughness of the second layer 105b may be reduced. In one or more embodiments, in the case where the surface roughness of the second layer 105b is reduced, the surface roughness of the buffer layer 110 formed on the second layer 105b may be also reduced compared to the case where the surface 100a is not cleaned. Accordingly, in the case where cleaning is performed on the surface 100a of the substrate 100 with an etchant containing fluorine (F) or a chemical solution of hydrofluoric acid (HF), hillocks formed on the surface of the second layer 105b may be reduced.

As described above, according to one or more embodiments, because the surface roughness of the substrate is increased, the occurrence of copper (Cu) hillocks may be prevented or reduced even when the buffer layer is deposited on the bottom metal layer including copper (Cu) under the condition of high temperatures (e.g., a temperature of 370° C. or higher). However, the scope of the present disclosure is not limited by this effect.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes and modifications in form and details may be made therein without departing from the spirit and scope of the present disclosure as defined by the following claims and equivalents thereof.

What is claimed is:

1. A method of manufacturing a display apparatus, the method comprising:
cleaning a surface of a substrate with an etchant containing fluorine (F) or a chemical solution of hydrofluoric acid (HF); and
forming a bottom metal layer on the surface of the substrate, the bottom metal layer comprising
a first layer and
a second layer on the first layer,
wherein a surface roughness of the substrate after cleaning is greater than a surface roughness of the substrate before cleaning.

2. The method of claim 1, wherein the first layer comprises a first material, and the second layer comprises a second material that is different from the first material.

3. The method of claim 2, wherein the first material comprises titanium (Ti), and the second material comprises copper (Cu).

4. The method of claim 1, further comprising, after the forming of the bottom metal layer, forming a buffer layer on the bottom metal layer.

5. The method of claim 4, wherein the buffer layer comprises a first buffer layer and a second buffer layer that are sequentially stacked.

6. The method of claim 5, wherein the first buffer layer and the second buffer layer comprise different materials.

7. The method of claim 6, wherein the first buffer layer comprises silicon nitride (SiNₓ), and the second buffer layer comprises silicon oxide (SiOₓ).

8. The method of claim 1, wherein, in an X-ray diffraction spectrum of the first layer by an X-ray diffraction analysis, a peak on a (002) plane is greater than a peak on a (103) plane.

9. The method of claim 1, wherein, in an X-ray diffraction spectrum of the second layer by an X-ray diffraction analysis, a peak on a (111) plane is greater than a peak on a (220) plane.

10. The method of claim 1, wherein, in an X-ray diffraction spectrum of the second layer by an X-ray diffraction analysis, a ratio (P1/P2) of a (200) plane peak (P1) to a (111) plane peak (P2) is 0.3 or more.

11. The method of claim 4, further comprising, after the forming of the buffer layer:
forming a semiconductor layer on the buffer layer; and
forming a gate electrode on the semiconductor layer.

12. A display apparatus comprising:
a substrate; and
a bottom metal layer on the substrate and comprising
a first layer and
a second layer on the first layer,
wherein, in an X-ray diffraction spectrum of the second layer by an X-ray diffraction analysis, a (111) plane peak is greater than a (220) plane peak.

13. The display apparatus of claim 12, wherein the first layer comprises a first material, and the second layer comprises a second material that is different from the first material.

14. The display apparatus of claim 13, wherein the first material comprises titanium (Ti), and the second material comprises copper (Cu).

15. The display apparatus of claim 12, further comprising a buffer layer on the bottom metal layer.

16. The display apparatus of claim 15, wherein the buffer layer comprises a first buffer layer and a second buffer layer that are sequentially stacked.

17. The display apparatus of claim 16, wherein the first buffer layer and the second buffer layer comprise different materials.

18. The display apparatus of claim 17, wherein the first buffer layer comprises silicon nitride (SiNₓ), and the second buffer layer comprises silicon oxide (SiOₓ).

19. The display apparatus of claim 12, wherein, in an X-ray diffraction spectrum of the first layer by an X-ray diffraction analysis, a peak on a (002) plane is greater than a peak on a (103) plane.

20. The display apparatus of claim 12, wherein, in an X-ray diffraction spectrum of the second layer by an X-ray diffraction analysis, a ratio (P1/P2) of a (200) plane peak (P1) to a (111) plane peak (P2) is 0.3 or more.
